(19) United States
(12) Patent Application Publication
(10) Pub. No.: US 2020/0273600 A1
(43) Pub. Date: Aug. 27, 2020

(54) LIGHT-TRANSMISSIVE CONDUCTIVE MATERIAL

(71) Applicant: MITSUBISHI PAPER MILLS LIMITED, Tokyo (JP)

(72) Inventor: Kazuhiko Sunada, Tokyo (JP)

(73) Assignee: MITSUBISHI PAPER MILLS LIMITED, Tokyo (JP)

(21) Appl. No.: 16/649,846

(22) PCT Filed: Sep. 10, 2018
(86) PCT No.: PCT/JP2018/033456

§ 371 Date: Mar. 23, 2020

(30) Foreign Application Priority Data
Sep. 22, 2017 (JP) 2017-182972

(51) Int. Cl. H01B 5/14; H05K 1/02; G06F 3/044

(52) U.S. Cl. CPC H01B 5/14; G06F 3/044; H05K 1/0298; H05K 1/0274

(57) ABSTRACT

An optically transparent conductive material includes: an optically transparent support; and an optically transparent conductive layer on the optically transparent support, the optically transparent conductive layer being electrically connected to a terminal area and including sensor parts extending in one direction, wherein the sensor parts are each made of an irregular net-like pattern of thin metal wires, each sensor part has varying widths and includes corridor portions where the width of the sensor part is relatively narrow and other portions where the width of the sensor part is relatively wide, and the following relation is satisfied: 1.05X≤A≤1.20X, where A is an average number of intersections in the net-like pattern of thin metal wires per unit area in the corridor portions, and X is an average number of intersections in the net-like pattern of thin metal wires per unit area in other portions.

### TECHNICAL FIELD

The present invention relates to an optically transparent conductive material mainly used for touchscreens. The present invention particularly relates to an optically transparent conductive material suitably used for optically transparent electrodes of projected capacitive touchscreens.

### BACKGROUND ART

Touchscreens are widely used as input means on displays of electronic devices such smartphones, personal digital assistants (PDAs), laptop computers, office automation equipment, medical equipment, and car navigation systems.

There are various touchscreens that utilize different position detection methods, such as optical, ultrasonic, surface capacitive, projected capacitive, and resistive touchscreens. In the case of resistive touchscreens, an optically transparent electrode as a touch sensor includes an optically transparent conductive material and a glass plate with an optically transparent conductive layer, which opposite each other across a spacer. In such a structure, an electrical current is applied to the optically transparent conductive material, and the voltage on the glass plate with an optically transparent conductive layer is measured. In the case of capacitive touchscreens, an optically transparent electrode as a touch sensor essentially includes an optically transparent conductive material including a support and an optically transparent conductive layer on the support. Owing to such a structure with no movable parts, the capacitive touchscreens have high durability and high optical transparency, and are thus used in various applications. In addition, projected capacitive touchscreens enables simultaneous multipoint detection, and are thus widely used in devices such as smartphones and tablet PCs.

Conventional optically transparent conductive materials used for optically transparent electrodes of touchscreens include an optically transparent conductive layer made of an indium-tin oxide (ITO) conductive film on a support. Yet, due to high refractive index and high surface reflectivity, ITO conductive films may reduce the optical transparency of optically transparent conductive materials. Additionally, due to low flexibility, ITO conductive films may crack when optically transparent conductive materials are bent, causing an increase in electrical resistance of the optically transparent conductive materials.

An optically transparent conductive material known as an alternative to ones that include optically transparent conductive layers made of ITO conductive films includes an optically transparent support and a pattern of thin metal wires as an optically transparent conductive layer on the support, in which, for example, a net-like pattern of thin metal wires is formed by adjusting the wire width and pitch of the pattern of thin metal wires and also by adjusting the shape of the pattern. This technique provides an optically transparent conductive material capable of maintaining a high optical transparency and having a high conductivity. With regard to the net-like pattern of thin metal wires (hereinafter also referred to as a “metal pattern”), it is known that a repetitive unit of any shape can be used. For example, Patent Literature 1 discloses repetitive units including triangles such as equilateral triangles, isosceles triangles, and right triangles; quadrangles such as squares, rectangles, rhombuses, parallelograms, and trapezoids; (regular) n-sided polygons such as (regular) hexagons, (regular) octagons, (regular) dodecagons, and (regular) icosagons; circles; ellipses; stars; and combinational patterns of two or more thereof.

A semi-additive method is known as a method of producing an optically transparent conductive material having the net-like metal pattern. In this method, a thin catalytic layer is formed on an optically transparent support, a resist pattern is formed thereon, a metal layer is stacked on a resist opening portion by plating, and lastly, a resist layer and a base metal protected by the resist layer are removed, whereby a metal pattern is formed.

Recently known techniques include a method in which a silver halide photosensitive material for a silver salt diffusion transfer process is used as a conductive material precursor. In this method, a silver halide photosensitive material (conductive material precursor) including at least a physical development nuclei layer and a silver halide emulsion layer in the stated order on an optically transparent support is acted on by a soluble silver salt-forming agent and a reducing agent in an alkaline solution, whereby a metal (silver) pattern is formed. This patterning method enables reproduction of patterns having a uniform wire width, and can also provide high conductivity with a narrower wire width compared to patterns produced by other methods, because silver has the highest conductivity of all metals. Further, a layer having a metal pattern produced by this method is advantageous in that it has higher flexibility and higher bending resistance than ITO conductive films.

Yet, since an optically transparent conductive material having such a metal pattern on an optically transparent support is superimposed on a display, the period of the metal pattern and the period of a display element interfere with each other, causing a problem of moire. Recent use of displays having various resolutions further complicates the problem.

To solve this problem, for example, Patent Literature 2 and the like propose methods of suppressing interference by using a traditional random pattern as a metal pattern. For example, such a traditional random pattern is described in “Mathematical Models of Territories—Introduction to Mathematical Engineering through Voronoi diagram” (Non-Patent Literature 1).

As disclosed in Patent Literature 3, a known example of a projected capacitive touch sensor is an optically transparent conductive material including two optically transparent conductive layers that include multiple linear electrodes connected to terminal areas via a peripheral wiring part, wherein the two optically transparent conductive layers are bonded together in such a manner that the linear electrodes of the respective optically transparent conductive layers are substantially orthogonal to each other via an insulation layer. Commonly used linear electrodes have a shape called “diamond pattern” in which intersections between linear electrodes of respective optically transparent conductive layers are contracted.

Linear electrodes made of the net-like pattern of thin metal wires have lower electrostatic discharge (ESD) resistance than ITO. It is because the thin metal wires have a lower electrical resistance than ITO, and a large amount of current can thus easily flow therethrough. The pattern of thin metal wires is formed from thin metal wires in the net-like form. The amount (area) of thin metal wires is smaller particularly in contracted portions of the diamond pattern than in other portions, and the current flowing through the thin wires is thus concentrated in the in contracted portions. This easily causes overcurrent.

Further, in the random metal pattern described above, a portion where the distribution of thin metal wires is scarce and a portion where the distribution is dense appear at random, so that the amount of thin metal wires per unit area is uneven. Disconnection due to ESD (electrostatic breakdown) easily occurs particularly when the amount of thin metal wires is small at the contracted portions of the diamond pattern where the current is concentrated.

Static electricity is known to be a problem particularly when an optically transparent conductive material is processed and produced in the form of a roll of a long sheet. Usually, countermeasures are taken on-site by using a static eliminator or maintaining the humidity at a certain level or higher. The optically transparent support which is an insulator is easily electrically charged. Friction and separation occur when the optically transparent support is unrolled or rolled up, causing static electricity. When the potential difference is high, electric discharge easily occurs in sensor parts which are conductive. In addition, a protective film is usually attached to protect a surface of the optically transparent conductive material. The protective film used for such an application is easily electrically charged. When the potential difference increases due to removal of the protective film, electric discharge easily occurs in the sensor parts. Thus, when such electric discharge occurs, disconnection (electrostatic breakdown) occurs at a portion susceptible to overcurrent in the sensor parts, which causes a significant decrease in the touchscreen yield.

In order to prevent electrostatic breakdown, Patent Literature 4 discloses an optically transparent conductive material provided with ground wires whose minimum inter-wire distance is smaller than the minimum inter-wire distance of peripheral wires. Patent Literature 5 discloses an optically transparent conductive material including a protective wire having electrical characteristics in which the electrical resistance decreases as the voltage increases. Yet, these materials are to prevent a momentary flow of current into the peripheral wiring part, and a technique that relates to the ESD resistance of the sensor parts is yet to be disclosed.

### CITATION LIST

### Patent Literatures

Patent Literature 1: JP 2013-30378 A

Patent Literature 2: JP 2011-216377 A

Patent Literature 3: JP 2006-511879 T

Patent Literature 4: JP 2016-15123 A

Patent Literature 5: JP 2016-162003 A

### Non-Patent Literature

Non-Patent Literature 1: Mathematical Models of Territories—Introduction to Mathematical Engineering through Voronoi diagram (published by Kyoritsu Shuppan Co., Ltd., February 2009)

### SUMMARY OF INVENTION

### Technical Problem

The present invention aims to provide an optically transparent conductive material that provides excellent visibility without causing moire even when superimposed on a display, in which sensor parts have excellent ESD resistance.

### Solution to Problem

The above problem is essentially solved by an optically transparent conductive material including: an optically transparent support; and an optically transparent conductive layer on the optically transparent support, the optically transparent conductive layer being electrically connected to a terminal area and including sensor parts extending in one direction, wherein the sensor parts are each made of an irregular net-like pattern of thin metal wires, each sensor part has varying widths and includes corridor portions where the width of the sensor part is relatively narrow and other portions where the width of the sensor part is relatively wide, and the following relation is satisfied: 1.05X≤A≤1.20X, where A is an average number of intersections in the pattern of thin metal wires per unit area in the corridor portions, and X is an average number of intersections in the pattern of thin metal wires per unit area in other portions.

Preferably, the sensor parts extending in one direction each have a shape in which the corridor portions appear periodically. Preferably, the corridor portions each have a width of 1 to 2 mm and a length of 1.5 to 3 mm in the direction in which the sensor parts extend. Preferably, when the unit area is the area of one corridor portion, the average number A of intersections is 10 or more. Preferably, the irregular net-like shape is a Voronoi diagram and/or a shape obtained by deforming a Voronoi diagram.

### Advantageous Effects of Invention

The present invention can provide an optically transparent conductive material that provides excellent visibility without causing moire even when superimposed on a display, in which the sensor parts have excellent ESD resistance.

### BRIEF DESCRIPTION OF DRAWINGS

FIG. 1 is a schematic view of a positional relationship between an upper electrode layer and a lower electrode layer.

FIG. 2 is a schematic view of an example of an optically transparent conductive material including the upper electrode layer and an optically transparent support.

FIG. 3 is a schematic view of an example of an optically transparent conductive material including the lower electrode layer and the optically transparent support.

FIG. 4 is an enlarged schematic view that illustrates a diamond pattern.

FIG. 5 is a view that illustrates the number of intersections in a corridor portion.

FIG. 6 is a view that illustrates a method of determining a ratio of intersections in sensor parts.

FIG. 7 is a view that illustrates an example of an optically transparent conductive material of the present invention.

FIG. 8 is a view of a method of producing a Voronoi diagram.

FIG. 9 is a view of a method of producing a deformed Voronoi diagram.

FIG. 10 is a view of a method of producing a Voronoi diagram.

### DESCRIPTION OF EMBODIMENTS

Hereinafter, the present invention is described in detail with reference to the drawings, but it is needless to say that the present invention is not limited to the following embodiments, and various alterations and modifications may be made without departing from the technical scope of the invention.

A projected capacitive touchscreen has a structure in which an upper electrode layer including multiple linear electrodes and a lower electrode layer including multiple linear electrodes are stacked together with an insulation layer therebetween. Using an optically transparent support as an insulation layer, an upper electrode layer which is an optically transparent conductive layer may be disposed on one surface of the optically transparent support, and a lower electrode layer which is an optically transparent conductive layer may be disclosed on the other surface. Alternatively, the upper electrode layer and the lower electrode layer may be disposed on separate optically transparent supports, and an optically transparent support side of the upper electrode layer may be bonded to an electrode layer side of the lower electrode layer with an optical clear adhesive (OCA).

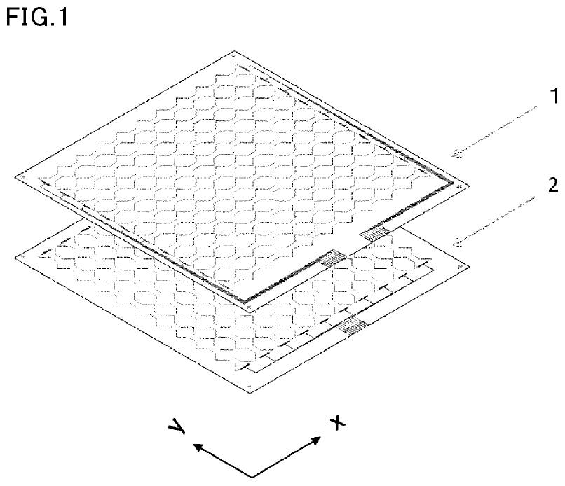

FIG. 1 is a schematic view of a positional relationship between an upper electrode layer and a lower electrode layer. FIG. 1 shows a positional relationship when an optically transparent support side of an upper electrode layer 1 and an electrode layer side of a lower electrode layer 2 are bonded together with an OCA (not shown). In practice, these layers are bonded together without any gaps via an OCA according to alignment marks at the four corners. The upper electrode layer 1 and the lower electrode layer 2 may be bonded to oppose each other, using an OCA as an insulation layer. In FIG. 1, the upper electrode layer is an electrode layer closer to a touch surface, and the lower electrode layer is an electrode layer away from the touch surface. The present invention also includes an embodiment in which the upper electrode layer and the lower electrode layer are inverted in the direction in which the linear electrodes extend. The angle between the upper linear electrodes and the lower linear electrodes is most preferably 90 degrees. The angle may be in the range of 60 degrees to 120 degrees, or in the range of 45 degrees to 135 degrees.

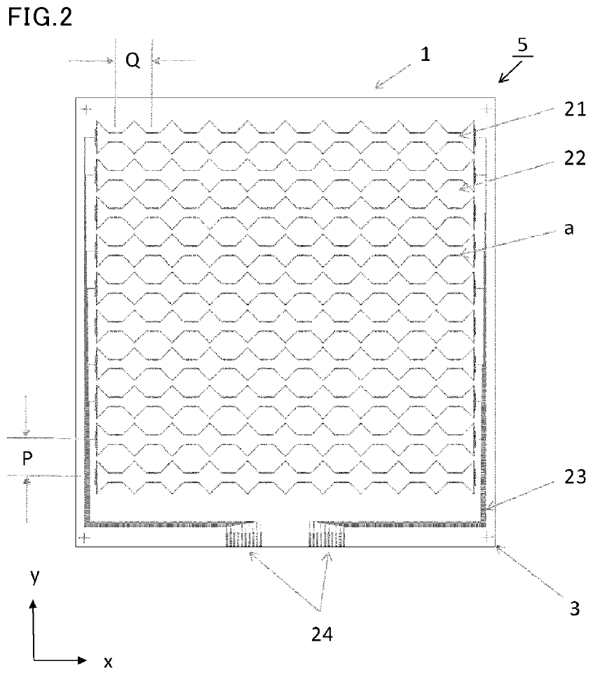

FIG. 2 is a schematic view of an example of an optically transparent conductive material including the upper electrode layer and the optically transparent support. In FIG. 2, an optically transparent conductive material 5 includes an optically transparent support 3 and the upper electrode layer 1 disposed on the optically transparent support 3. The upper electrode layer 1 includes sensor parts 21 that are linear electrodes each having a net-like pattern of thin metal wires, dummy parts 22, a peripheral wiring part 23, and terminal areas 24. Here, the sensor parts 21 and the dummy parts 22 are formed in net-like patterns of thin metal wires. However, expediently, the ranges of these components are shown with virtual outlines “a” (imaginary lines). The virtual outlines “a” are boundary lines that separate the dummy parts 22 from the sensor parts 21. FIG. 2 also shows an example in which the sensor parts 21 and the dummy parts 22 are formed on the optically transparent support 3 by providing disconnection parts in the patterns of thin metal wires along the virtual outlines “a” (i.e., by providing disconnection parts to the pattern of thin metal wires located at boundaries between the sensor parts and the dummy parts).

The sensor parts 21 in FIG. 2 are electrically connected to the terminal areas 24 via the peripheral wiring parts 23. As the sensor parts 21 are electrically connected to the outside via the terminal areas 24, changes in the capacitance sensed by the sensor parts 21 can be captured. Disconnection parts are provided along the virtual outlines “a”, whereby the dummy parts 22 are formed. The dummy parts 22 are insulated from the sensor parts 21 by the disconnection parts. Thus, the dummy parts 22 are not electrically connected to the peripheral wiring parts 23 and the terminal areas 24. In the present invention, all the patterns of thin metal wires not electrically connected to the terminal areas 24 are the dummy parts 22. In the present invention, the peripheral wiring parts 23 and the terminal areas 24 are not particularly required to be optically transparent when, for example, they are disposed in a frame. Thus, they may be formed in a solid pattern (a pattern without optical transparency). When optical transparency is required, the peripheral wiring parts 23 and the terminal areas 24 may be formed in net-like patterns of thin metal wires as in the sensor parts 21 and the dummy parts 22. The description of the present invention continues below with reference to the upper electrode layer, but the same description applies to the lower electrode layer, except that the direction (xy in the figure) is different.

The upper electrode layer 1 shown in FIG. 2 is defined by multiple sensor parts 21 extending in a first direction (x-direction in FIG. 2), wherein in a plane of the optically transparent conductive layer, the multiple sensor parts 21 are aligned with a period P in a second direction (y-direction in FIG. 2) perpendicular to the first direction, with the dummy part 22 between each sensor part 21. The period P of the sensor parts 21 can be set to any length within a range that the resolution of the touch sensor is maintained. A preferred range of the period P is more than 3 mm but not more than 20 mm. The width of each sensor part 21 (the length of each sensor part 21 in the y direction) can also be set to any length within a range that the resolution of the touch sensor is maintained. The shape and width of the dummy parts 22 can also be set to any shape and width correspondingly. A preferred range of the width at the widest portion of the sensor parts is more than 2 mm but not more than 15 mm.

The sensor parts 21 can be formed in a pattern with a period in the first direction (x-direction in the figure). FIG. 2 shows a preferred example (an example of a diamond pattern) of the present invention in which the sensor parts 21 include contracted portions with a period Q.

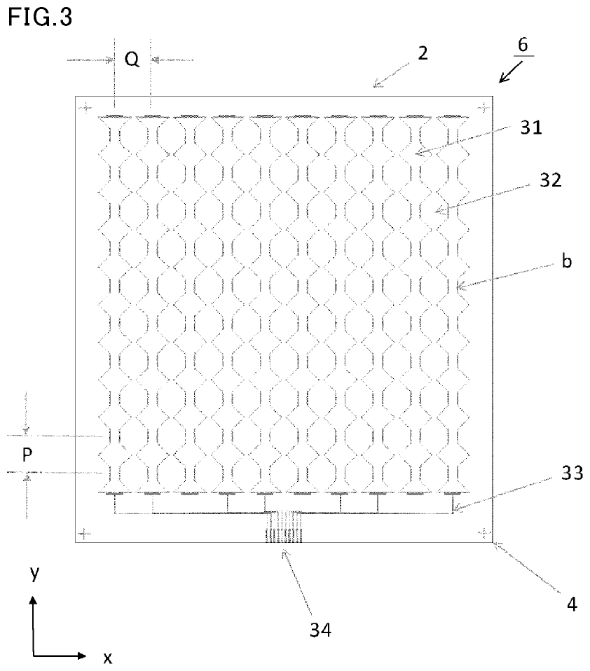

FIG. 3 is a schematic view of an example of an optically transparent conductive material including the lower electrode layer and the optically transparent support. In FIG. 3, an optically transparent conductive material 6 includes an optically transparent support 4 and the lower electrode layer 2 disposed on the optically transparent support 4. The lower electrode layer 2 includes sensor parts 31 that are linear electrodes having a net-like pattern of thin metal wires, dummy parts 32, a peripheral wiring part 33, and a terminal area 34. Here, the sensor parts 31 and the dummy parts 32 are formed in net-like pattern of thin metal wires. Yet, expediently, these components are outlined by virtual outlines “b” (virtual lines). The virtual outlines “b” are boundary lines that separate the sensor parts 31 from the dummy parts 32. FIG. 3 also shows an example in which the sensor parts 31 and the dummy parts 32 are formed on the optically transparent support 4 by providing disconnection parts in the patterns of thin metal wires along the virtual outlines “b” (i.e., by providing disconnection parts to the pattern of thin metal wires located at boundaries between the sensor parts and the dummy parts).

The lower electrode layer 2 shown in FIG. 3 is defined by multiple sensor parts 31 extending in the second direction (y-direction in FIG. 3), wherein in a plane of the optically transparent conductive layer, the sensor parts 31 are aligned with the period Q in the first direction (x-direction in FIG. 3) perpendicular to the second direction, with the dummy part 32 between each sensor part 31. The period Q of the sensor part 31 can be set to any length within a range that the resolution of the touch sensor is maintained. A preferred range of the period Q is more than 3 mm but not more than 20 mm. The width of each sensor part 31 (i.e., the length of each sensor part 31 in the x-direction) can also be set to any width within a range that the resolution of the touch sensor is maintained. The shape and width of the dummy parts 32 can also be set to any shape and width correspondingly. A preferred range of the width at the widest portion of the sensor parts is more than 2 mm but not more than 15 mm.

In the optically transparent conductive material of the present invention, each sensor part has varying widths and includes corridor portions where the width of the sensor part is relatively narrow and other portions where the width of the sensor part is relatively wide.

The virtual outlines of the sensor parts are indicated by boundary lines of regions defined by connecting the disconnection parts of the thin metal wires separating the sensor parts from the dummy parts. When the virtual outlines of the sensor parts are linear and parallel to each other in the corridor portions, only a portion where the sensor part is the narrowest is a corridor portion. When the virtual outlines of the sensor parts are not linear or parallel to each other, a portion whose width is not more than 1.1 times the narrowest width of the sensor part is a corridor portion.

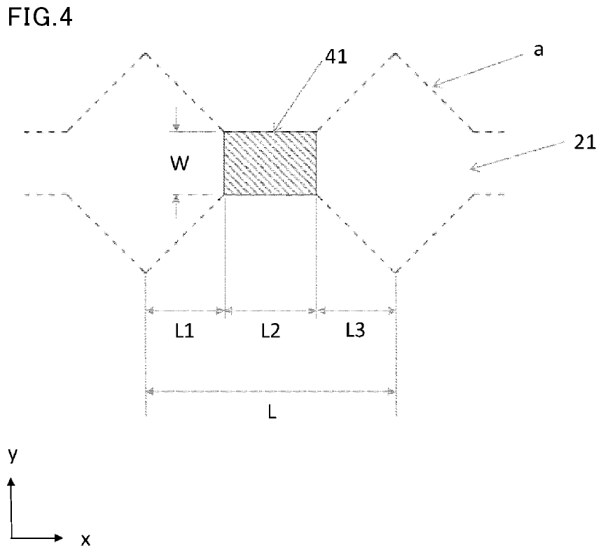

FIG. 4 is an enlarged schematic view that illustrates a diamond pattern. In FIG. 4, the sensor part 21 extends in the first direction (x-direction in the figure). The width is not constant, and varies along the x-direction. L2 is the narrowest portion. L1 and L3 are portions where the width continuously varies between the narrowest portion and the widest portion. The width of the narrowest portion of the sensor part is indicated by W. A portion 41 corresponding to L2 where the sensor part is the narrowest is a corridor portion. Other portions in the sensor part, which correspond to L1 and L3, are also referred to as diamond portions. As described above, in the present invention, the sensor parts extending in one direction each preferably have a shape in which the corridor portions appear periodically. A preferred range of the period L is more than 3 mm but not more than 20 mm.

The size of the corridor portions can be set to any size according to the performance of the touch sensor. Yet, when W is too small, it increases the electrical resistance of the sensor parts. When W is too wide, it results in an increased area where the corridor portions overlap the sensor parts in the lower electrode. Disadvantageously, both cases cause a decrease in the performance of the touch sensor. L2 can be suitably determined according to the size of the width W of the corridor portions in the lower electrode layer. The width W of each corridor portion is preferably in the range of 1 to 2 mm, and the length L2 of each corridor portion is preferably in the range of 1.5 to 3 mm. FIG. 4 shows an example in which W=1.5 mm and L2 2.25 mm. In the example shown in FIG. 4, the area of the corridor portion is 3.375 mm². In the present invention, expediently, the area of one corridor portion is used as the unit area for counting the number of intersections.

In the present invention, when the length (L2 in FIG. 4) of the corridor portion is too short, the area of the corridor portion may be so small that intersections (described later) may not be included in a region (W×L2 in FIG. 4) for counting the intersections, or the number of intersections included in the region may be so small that the margin of error in the number of intersection per unit area may be high. Thus, the length of the corridor portion is preferably long enough to allow 10 or more intersections to be included in the region for counting the intersections.

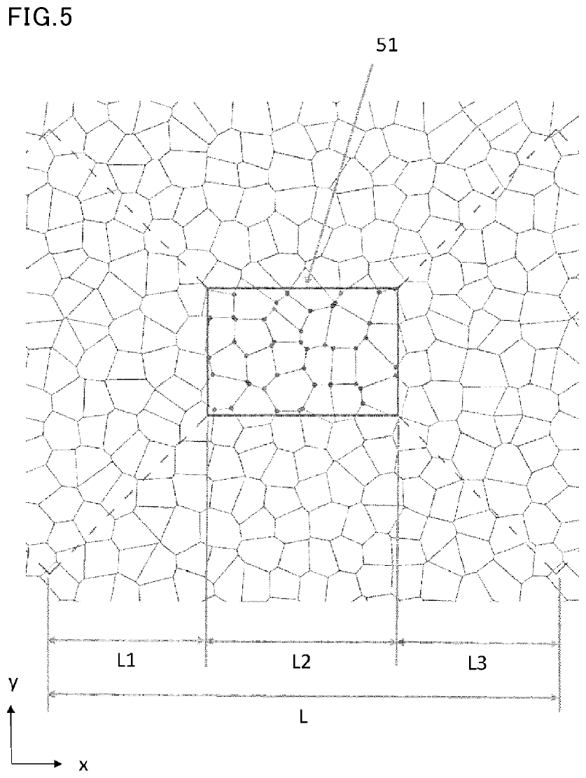

FIG. 5 is a view that illustrates the number of intersections in a corridor portion. The net-like pattern shown in FIG. 5 is a specific example of the metal pattern defining the diamond pattern shown in FIG. 4. The metal pattern is a Voronoi diagram formed in an irregular net-like pattern. In FIG. 5, a region corresponding to the corridor portion is indicated by a frame 51. In FIG. 5, intersections in the net-like pattern in the corridor portion are indicated by round dots. As shown in FIG. 5, the intersections are portions where segments intersect each other. In a Voronoi diagram, in rare cases, four or more segments share one intersection as an end point of each of these segments. Yet, in most cases, three segments share one intersection as an end point. In other words, three segments extend from most intersections. The number of intersections present in the corridor portion shown in the frame 51 is 49.

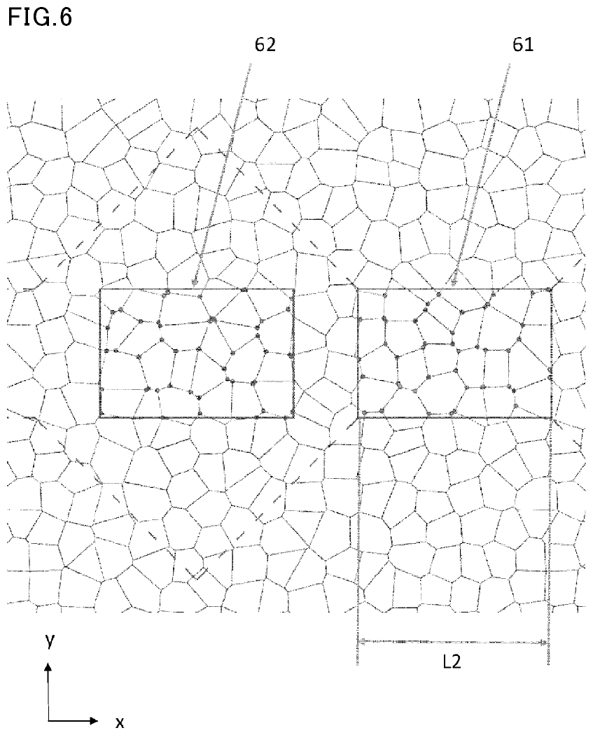

FIG. 6 is a view that illustrates a method of determining a ratio of intersections in the sensor parts.

A frame 61 shows a region corresponding to a corridor portion, and the number of intersections in the corridor portion is also 49, as in the corridor portion shown in FIG. 5. A frame 62 has a shape congruent to the shape of the frame 61, and indicates a portion other than the corridor portion in the sensor part. The frame 62 may be situated in any portion as long as it is not the corridor portion in the sensor part. Yet, it is preferably situated at the center of the diamond portion as shown in FIG. 6. The number of intersections in the frame 62 is 51. In this case, the ratio of the number of intersections in the frame 61 to the number of intersections in the frame 62 is 49/51≈0.96.

An optically transparent conductive material which is obtained by repeatedly arranging the metal patterns shown in FIG. 6 does not satisfy the relation: 1.05X≤A≤1.20X because A is 49 and X is 51, where A represents the average number of intersections in the net-like pattern of thin metal wires per unit area (i.e., the frame 61 in FIG. 6) in all the corridor portions defining the sensor parts, and X represents the average number of intersections in the net-like pattern of thin metal wires per unit area (i.e., the frame 62 in FIG. 6) in all the diamond portions defining the sensor parts. Thus, the optically transparent conductive material which is obtained by periodically arranging the metal pattern shown in FIG. 6 is not the optically transparent conductive material of the present invention.

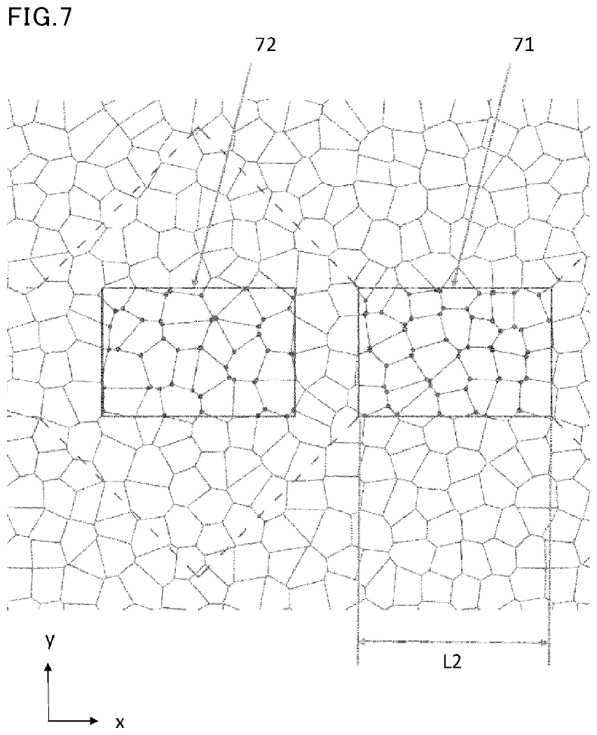

FIG. 7 is a view that illustrates an example of the optically transparent conductive material of the present invention. A frame 71 shows a region corresponding to a corridor portion, and the number of intersections in the corridor portion is 54. A frame 72 has a shape congruent to the shape of the frame 71, and indicates the same place as the frame 62 in FIG. 6. Thus, the number of intersections in the frame 72 is also 51, as in the number of intersections in the frame 62 shown in FIG. 6. In this case, the ratio of the number of intersections in the frame 71 to the number of intersections in the frame 72 is 54/51≈1.06. The optically transparent conductive material of the present invention which is obtained by repeatedly arranging the metal patterns shown in FIG. 7 satisfies the relation: 1.05X≤A≤1.20X because A is 54 and X is 51, where A represents the average number of intersections in the net-like pattern of thin metal wires per unit area in all the corridor portions of the sensor parts, and X represents the average number of intersections in the net-like pattern of thin metal wires per unit area in all the diamond portions of the sensor parts. In other words, the ratio of A to X (A/X) is 1.05 to 1.20. When A is smaller than 1.05X (i.e., A/X is less than 1.05), the ESD resistance will be insufficient. When A is larger than 1.20X (i.e., A/X is more than 1.20), the difference in optical transparency between the corridor portions and other portions will be large, which is undesirable in terms of visibility.

The above description described the method of determining A and X, which can be expediently used for the diamond pattern that is a preferred shape of the sensor part in the present invention. When the shape of the sensor part is different from the diamond pattern or is not a repeated pattern with a period in the first direction, A can be determined by counting the total number of intersections included in all the corridor portions defining the sensor parts and by multiplying the total number by the ratio of the unit area to the total area of the corridor portions. X can be determined by counting the total number of intersections included in all the other portions defining the sensor portions (i.e., all the portions other than the corridor portions) and by multiplying the total number by the ratio of the unit area to the total area of the other portions.

Next, irregular net-like patterns of thin metal wires forming the sensor parts and the dummy parts in the present invention are described. Examples of the irregular pattern include those obtained with irregular geometric shapes typified by, for example, a Voronoi diagram, a Delaunay diagram, and a Penrose tiling pattern. In the present invention, a net-like pattern formed with Voronoi edges based on generators (hereinafter referred to as a “Voronoi diagram”) is preferably used. With the use of a Voronoi diagram, it is possible to obtain an optically transparent conductive material that can be used to provide a touchscreen with excellent visibility. Voronoi diagrams are known diagrams that have been applied in various fields including the field of information processing.

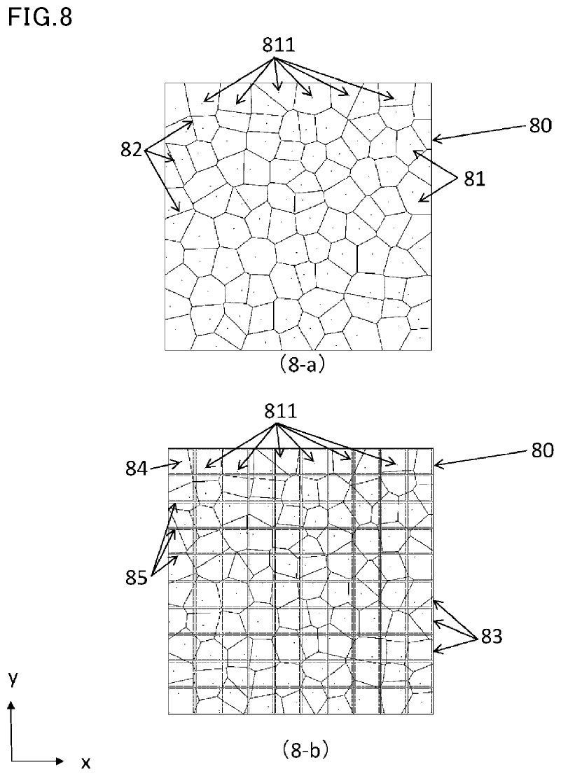

FIG. 8 is a view of a method of producing a Voronoi diagram. In FIG. 8 (8-a), when multiple generators 811 are arranged on a plane 80, the plane 80 is divided by boundary lines 82 in such a manner that a region 81 (referred to as a “Voronoi region”) closest to any one generator 811 is separated from other regions 81 each closest to a different generator 811. The boundary lines 82 each between two different regions 81 are called Voronoi edges. A Voronoi edge is a part of a perpendicular bisector of a line segment connecting any generator to its adjacent generator. A diagram formed of a collection of Voronoi edges is referred to as a Voronoi diagram. The term “intersection” as used herein refers to a point shared by boundaries of three or more Voronoi regions. The intersection is referred to as a “Voronoi point”.

A method for arranging generators is described with reference to FIG. 8 (8-b). In the present invention, a method for dividing the plane 80 into polygons and randomly arranging the generators 811 in the divided sections is preferably used. Examples of the method for dividing the plane 80 include one described below. First, the plane 80 is tiled with multiple polygons of having the same shape or of two or more different shapes (hereinafter, referred to as “original polygons”). Subsequently, for each original polygon, an enlarged/reduced polygon is produced in which each vertex is located on a straight line from the center of gravity to each vertex of the original polygon or on an extended line of the straight line, at any percentage of the distance of the straight line from the center of gravity to each vertex of the original polygon. Then, the plane 80 is divided by these enlarged/reduced polygons. After dividing the plane 80 as described above, generators are randomly arranged in the enlarged/reduced polygons, with one generator in one enlarged/reduced polygon. In FIG. 8 (8-b), the plane 80 is tiled with original polygons 83 that are squares. Subsequently, the center of gravity 84 of each original polygon 83 is connected by a straight line to each vertex of the original polygon 83, and a reduced polygon 85 is produced by connecting, as vertices, points on the straight lines at 80% of the distance from the center of gravity 84 to the vertices of the original polygon 83. Lastly, generators 811 are randomly arranged in such reduced polygons 85, with one generator 811 in one reduced polygon 85.

In the present invention, in order to prevent “grains”, it is preferred to tile the plane with the original polygons 83 of the same shape and the same size as shown in FIG. 8 (8-b). Here, the term “grains” refers to a phenomenon in which high-density portions and low-density portions appear specifically in a random diagram. In addition, when the center of gravity of each original polygon is connected to each vertex of the original polygon by a straight line or when such a straight line is extended, preferably, each vertex of the enlarged/reduced polygon is located on the straight line or the extended line at 10 to 300% of the distance from the center of gravity to each vertex of the original polygon. When the percentage is more than 300%, the phenomenon of grains may appear. When the percentage is less than 10%, high regularity remains in the Voronoi diagram, which may cause moire when the optically transparent conductive material is superimposed on a display.

Preferred shapes of the original polygon are quadrangles (such as squares, rectangles, and rhombuses), triangles, and hexagons. In order to prevent the phenomenon of grains, more preferred are quadrangles, and particularly preferred are rectangles each having a longer side to shorter side ratio of 1:0.7 to 1:1. The length of one side of the original polygon is preferably 100 to 2000 μm, more preferably 120 to 800 μm. In the present invention, the Voronoi edge is most preferably a straight line, but a different line such as a curved line, a wavy line, or a zigzag line may also be used. The wire width of each metal pattern of the sensor parts 21 and the dummy parts 22 is preferably 1 to 20 μm, more preferably 2 to 7 μm, in order to achieve conductivity and optically transparent in a balanced manner.

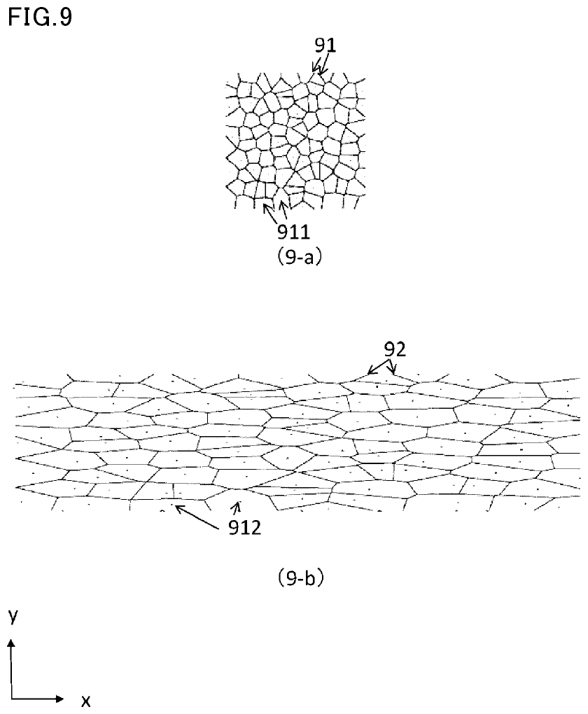

The irregular net-like shape in the present invention is also preferably a shape obtained by enlarging or reducing the Voronoi diagram obtained by the above method in any direction. FIG. 9 is a view of a method of producing a deformed Voronoi diagram. FIG. 9 (9-a) shows a Voronoi diagram before enlargement or reduction. When the Voronoi diagram in FIG. 9 (9-a) is enlarged by four times in the x-direction and not changed in the y-direction, the result is as shown in FIG. 9 (9-b). Voronoi edges 91 in FIG. 9 (9-a) correspond to edges 92 in FIG. 9 (9-b), and generators 911 in FIG. 9 (9-a) correspond to dots 912 in FIG. 9 (9-b) (the positional relationship between these edges and dots is different from the positional relationship between the Voronoi edges and generators in the Voronoi diagram). The generators are indicated by dots for the sake of description in FIG. 8 and FIG. 9, but no generators or dots are present in the actual thin metal wires. In the present invention, a single electrode layer may include a combination of a net-like pattern of thin metal wires based on a Voronoi diagram and a net-like pattern of thin metal wires based on a shape obtained by enlarging or decreasing a Voronoi diagram in any direction.

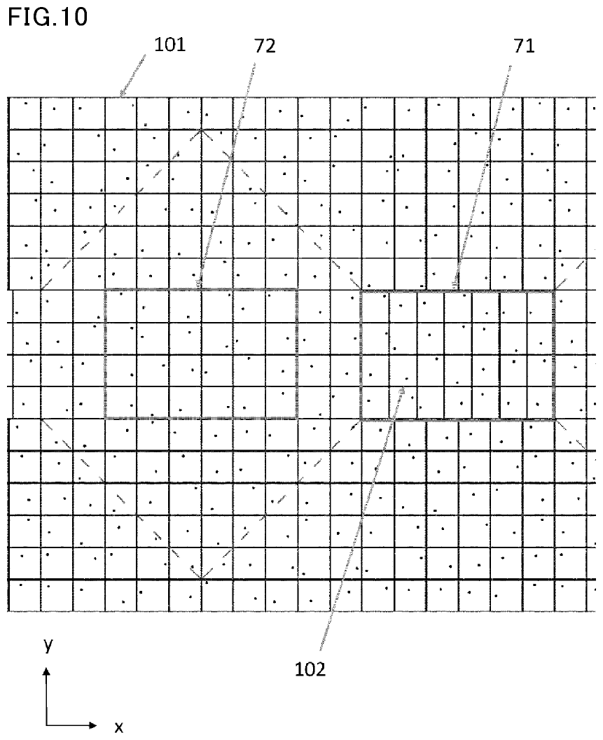

FIG. 10 is a view of a method of producing a Voronoi diagram, and is also a view showing positions of generators for producing a Voronoi diagram shown in FIG. 7. In FIG. 10, the plane excluding the frame 71 that indicates the region corresponding to the corridor portion is tiled with original polygons 101, and the frame 71 is tiled with original polygons 102. The frame 72 having the same area as the frame 71 is tiled with 24 original polygons 101 (6 columns in the x-direction×4 columns in the y-direction). The frame 71 is tiled with 28 original polygons 102 (7 columns in the x-direction×4 columns in the y-direction). Next, a reduced polygon is produced by connecting points at 80% of the distance from the center of gravity of the original polygon to the vertices of the original polygon. Then, generators are randomly arranged in the reduced polygons, with one generator in each reduced polygon. The number of generators is the same as the number of original polygons. There are 24 generators in the frame 72, and 28 generators in the frame 71. As described above, the region corresponding to the corridor portion is tiled with smaller original polygons than those used in the other portions. This makes it possible to increase the number of generators in the region corresponding to the corridor portion. The Voronoi diagram shown in FIG. 7 can be obtained by using the generators disposed as described above.

As shown in FIG. 7, a Voronoi diagram is produced by arranging more generators in the corridor portions than in the other portions, whereby, ultimately, more Voronoi points (i.e., intersections) can be obtained in the corridor portions than in the other portions. Since the generators are created at random locations in the enlarged/reduced polygons, it is difficult to determine which portion an intersection belongs to, especially when the intersection is located at a boundary line between the corridor portion and the other portion. Thus, the number of generators in the corridor portion and the number of intersections in the corridor portion are not necessarily determined unambiguously. Yet, as an overall trend, the number of generators has a proportionate relationship to the number of intersections. In the present invention, the resulting ratio of the average number A of intersections in the corridor portions to the average number X of intersections in the portions other than the corridor portions in the sensor part is 1.05 to 1.20.

As described above for FIG. 2, the sensor parts are not electrically connected to the dummy parts. The dummy parts 22 are formed by providing disconnection parts along the virtual outlines “a”. Further, multiple disconnection parts may be provided in the dummy parts, in addition to along the virtual outlines “a”. The disconnection length (i.e., the length of a portion where the thin metal wire is disconnected in the disconnection part) is preferably 3 to 100 μm, more preferably 5 to 20 μm.

In the present invention, the sensor parts 21 and the dummy parts 22 are each formed in a net-like metal pattern. Preferred examples of the metal include gold, silver, copper, nickel, aluminium, and composite materials thereof. Peripheral wiring parts 23 and terminal areas 24 are also preferably formed in metal patterns made of the same metal composition as that of the sensor parts 21 and the dummy parts 22 in view of production efficiency. Examples of the method for forming these metal patterns include known methods such as a method in which a silver halide photography photosensitive material is used; a method in which a silver image (pattern of thin silver wires) obtained using a silver halide photography photosensitive material by the above method is electroless plated or electroplated; a method in which conductive ink such as silver ink or copper ink is printed by a screen printing method; a method in which conductive ink such as silver ink or copper ink is printed by an ink-jet method; a method in which a conductive layer is formed by vapor deposition or sputtering, and a resist film is formed thereon, followed by exposure, development, and etching in a sequential manner, and then resist layer removal; and a method in which metal foil such as copper foil is attached, and a resist film is formed thereon, followed by exposure, development, and etching in a sequential manner, and then resist layer removal. Particularly preferred is a silver salt diffusion transfer process because a metal pattern to be produced can be made thin and a very fine metal pattern can be easily formed with this process.

With regard to the thickness of the metal pattern produced by the above techniques, a pattern that is too thick may be difficult to post-process (e.g., bonding to other members), and a pattern that is too thin may fail to provide necessary conductivity to a touchscreen. Thus, the thickness is preferably 0.01 to 5 μm, more preferably 0.05 to 1 μm.

In the optically transparent conductive material of the present invention, the total light transmittance of the sensor parts 21 and the total light transmittance of the. dummy parts 22 are preferably 80% or more, more preferably 85% or more, particularly preferably 88.5% or more. In addition, the difference between the total light transmittance of the sensor parts 21 and the total light transmittance of the dummy parts 22 is preferably within 0.5%, more preferably within 0.1%, particularly preferably 0%. The haze value of the sensor parts 21 and the dummy part 22 is preferably 2 or less. Further, the b* value indicating the hue of the sensor parts 11 and the dummy parts 12 is preferably 2 or less, more preferably 1 or less.

The optically transparent support of the optically transparent conductive material of the present invention is preferably a known optically transparent support such as glass, polyester resins such as polyethylene terephthalate (PET) or polyethylene naphthalate (PEN), acrylic resin, epoxy resin, fluororesin, silicone resin, polycarbonate resin, diacetate resin, triacetate resin, polyarylate resin, polyvinyl chloride, polysulfone resin, polyether sulfone resin, polyimide resin, polyamide resin, polyolefin resin, or cyclic polyolefin resin. The term “optical transparency” as used herein means that the total light transmittance is 60% or higher. The total light transmittance of the optically transparent support is preferably 80% or higher. The thickness of the optically transparent support is preferably 50 μm to 5 mm. The optically transparent support may also include a known layer, such as an anti-fingerprint layer, a hard coat layer, an antireflection layer, and an antiglare layer.

In the present invention, an OCA may be used to bond the optically transparent support side of the upper electrode layer 1 to the electrode layer side of the lower electrode layer 2 as shown in FIG. 1, or may be used to provide a structure in which these electrode layers are opposite to each other (a structure including an OCA as an insulation layer). In such a case, an adhesive for the OCA is preferably a known one, such as a rubber-based adhesive, an acrylic adhesive, a silicone-based adhesive, or a urethane-based adhesive, which has a resin composition that becomes optically transparent after bonding.

### EXAMPLES

The present invention is described in details with reference to examples below, but the present invention is not limited to the following examples as long as modifications are within the scope of the present invention.

### <Optically Transparent Conductive Material 1>: Comparative Example

The optically transparent support was a 100-μm-thick polyethylene terephthalate film having a total light transmittance of 92%.

Next, in accordance with the following formulation, a physical development nuclei layer coating liquid was prepared, applied to the optically transparent support, and dried to form a physical development nuclei layer.

### Preparation of Palladium Sulfide Sol

### Liquid A

| Palladium chloride | 5 | g |
|---|---|---|
| Hydrochloric acid | 40 | ml |
| Distilled water | 1000 | ml |
| Liquid B | | |
| Sodium sulfide | 8.6 | g |
| Distilled water | 1000 | ml |

Liquid A and Liquid B were mixed with stirring for 30 minutes, and then passed through a column filled with an ion exchange resin, whereby a palladium sulfide sol was obtained.

### <Preparation of Physical Development Nuclei Layer Coating Liquid>Amount Per m² of Silver Halide Photosensitive Material

| | | |
|---|---|---|
| Palladium sulfide sol prepared above | 0.4 | mg |
| (based on solids content) | | |
| 2% by mass aqueous glyoxal solution | 200 | mg |
| Surfactant represented by formula (1) below | 4 | mg |
| Denacol ® EX-830 | 25 | mg |
| (polyethylene glycol diglycidyl ether available from | | |
| Nagase ChemteX Corporation) | | |
| 10% by mass aqueous solution of EPOMIN ® | 500 | mg |
| HM-2000 (polyethylenimine available | | |
| from Nippon Shokubai Co., Ltd.; | | |
| average molecular weight of 30,000) | | |

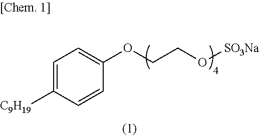

Subsequently, an intermediate layer, a silver halide emulsion layer, and a protective layer having compositions shown below were applied to the physical development nuclei layer in the stated order from the closest to the optically transparent support, followed by drying, whereby a silver halide photosensitive material was obtained. The silver halide emulsion was produced by a common double jet mixing method for photographic silver halide emulsions. The silver halide emulsion was prepared from 95% by mole of silver chloride and 5% by mole of silver bromide to have an average particle diameter of 0.15 μm. The silver halide emulsion obtained as above was subjected to gold and sulfur sensitization using sodium thiosulfate and chloroauric acid by the usual method. The silver halide emulsion obtained as above contained 0.5 g of gelatin per gram of silver.

### <Composition of Intermediate Layer>Amount Per m² of Silver Halide Photosensitive Material

| | | |
|---|---|---|
| Gelatin | 0.5 | g |
| Surfactant represented by formula (1) above | 5 | mg |
| Dye represented by formula (2) below | 5 | mg |

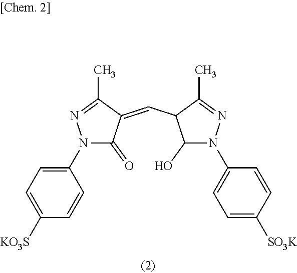

### <Composition of Silver Halide Emulsion Layer>Amount Per m² of Silver Halide Photosensitive Material

| Gelatin | 0.5 | g |
|---|---|---|
| Silver halide emulsion | 3.0 | g in |
| silver equivalent | | |
| 1-Phenyl-5-mercaptotetrazole | 3 | mg |
| Surfactant represented | 20 | mg |

by formula (1) above

### <Composition of Protective Layer>Amount Per m² of Silver Halide Photosensitive Material

| Gelatin | 1 | g |
|---|---|---|
| Amorphous silica matting | 10 | mg |
| agent (average | | |
| particle size: 3.5 μm) | | |
| Surfactant represented | 10 | mg |

by formula (1) above

The silver halide photosensitive material obtained as above was brought into tight contact with a transparent manuscript having the pattern image shown in FIG. 2, and light exposure was performed through a resin filter which cuts off light of 400 nm or less, using a contact printer having a mercury lamp as a light source. The period P of the sensor parts 21 in the transparent manuscript was 6.0 mm, and the period Q of the contracted portions of the diamond pattern was 6.0 mm.

In a transparent manuscript having the pattern image shown in FIG. 2, the patterns of the sensor parts 21 and the dummy parts 22 were produced by repeatedly attaching the Voronoi diagram shown in FIG. 6 (i.e., an image pattern in a region defined by “the total width of one diamond portion and one corridor portion in the x-direction”×“the entire width in the y-direction” in FIG. 6), with the period Q in the x-direction and the period P in the y-direction in FIG. 2. The wire width of the Voronoi diagram was 5 μm. A disconnection part having a disconnection length (i.e., the length of a portion where the thin metal wire is disconnected in the disconnection part) of 20 μm was provided on a Voronoi edge, at each intersection between the Voronoi edge and a virtual outline of the sensor part (i.e., a boundary line that separates the sensor part from the dummy part.

Subsequently, the silver halide photosensitive material was immersed in the diffusion transfer developer shown below at 20° C. for 60 seconds. Then, the silver halide emulsion layer, the intermediate layer, and the protective layer were washed off with warm water at 40° C. and dried, whereby an optically transparent conductive material 1 having a pattern of thin metal wires (hereinafter also referred to as a “metal silver image”) as an upper electrode layer was obtained. All the metal silver images on the optically transparent conductive layers of the optically transparent conductive material obtained above and other optically transparent conductive materials shown below each had the same shape and the same wire width as in the image pattern of the transparent manuscript used. The area of the corridor portion was used as the unit area. The average number A of intersections in the corridor portion was 49, and the average number X of intersections in the unit area at the center of the diamond portion was 51.

### Composition of Diffusion Transfer Developer

| | | |
|---|---|---|
| Potassium hydroxide | 25 | g |
| Hydroquinone | 18 | g |
| 1-Phenyl-3-pyrazolidone | 2 | g |
| Potassium sulfite | 80 | g |
| N-methylethanolamine | 15 | g |
| Potassium bromide | 1.2 | g |

The total volume was made up to 1000 ml with water. The pH was adjusted to 12.2.

### <Optically Transparent Conductive Material 2>: Present Invention

An optically transparent conductive material 2 was obtained as in the optically transparent conductive material 1, except that in a transparent manuscript having the pattern image shown in FIG. 2, the patterns of the sensor parts 21 and the dummy parts 22 were produced by repeatedly attaching the Voronoi diagram shown in FIG. 7 (i.e., an image pattern in a region defined by “the total width of one diamond portion and one corridor portion in the x-direction”×“the entire width in the y-direction” in FIG. 7), with the period Q in the x-direction and the period P in the y-direction in FIG. 2. The average number A of intersections in the corridor portion was 54, and the average number X of intersections in the unit area at the center of the diamond portion was 51.

### <Optically Transparent Conductive Material 3>: Present Invention

An optically transparent conductive material 3 was obtained as in the optically transparent conductive material 2, except that in a transparent manuscript having the pattern image shown in FIG. 2, the pattern of each of the sensor parts 21 and the dummy parts 22 was a Voronoi diagram produced by changing the number (i.e., the number of generators) of the rectangular original polygons (all having the same shape and the same size) in the frame 71 shown in FIGS. 10 to 30 (6 columns in the x-direction×5 columns in the y-direction). The average number A of intersections in the corridor portion was 60, and the average number X of intersections in the unit area at the center of the diamond portion was 51.

### <Optically Transparent Conductive Material 4>: Comparative Example

An optically transparent conductive material 4 was obtained as in the optically transparent conductive material 2, except that in a transparent manuscript having the pattern image shown in FIG. 2, the pattern of each of the sensor parts 21 and the dummy parts 22 was a Voronoi diagram produced by changing the number (i.e., the number of generators) of the rectangular original polygons (all having the same shape and the same size) in the frame 71 shown in FIGS. 10 to 32 (8 columns in the x-direction×4 columns in the y-direction). The average number A of intersections in the corridor portion was 62, and the average number X of intersections in the unit area at the center of the diamond portion was 51.

### <Optically Transparent Conductive Material 5>: Comparative Example

An optically transparent conductive material 5 was obtained as in the optically transparent conductive material 2, except that in a transparent manuscript having the pattern image shown in FIG. 2, the pattern of each of the sensor parts 21 and the dummy parts 22 was a Voronoi diagram produced by changing the number (i.e., the number of generators) of the rectangular original polygons (all having the same shape and the same size) in the frame 71 shown in FIGS. 10 to 35 (7 columns in the x-direction×5 columns in the y-direction). The average number A of intersections in the corridor portion was 64, and the average number X of intersections in the unit area at the center of the diamond portion was 51.

### <Optically Transparent Conductive Material 6>: Comparative Example

An optically transparent conductive material 6 including a metal silver image as the lower electrode layer was produced as in the optically transparent conductive material 1, except a different transparent manuscript was used which was produced by changing the pattern of the transparent manuscript from the one shown in FIG. 2 to the one shown in FIG. 3, reversing the x-direction and the y-direction in the Voronoi diagram shown in FIG. 6 (i.e., an image pattern in a region defined by. “the total width of one diamond portion and one corridor portion in the x-direction”×“the entire width in the y-direction” in FIG. 6), and repeatedly attaching the Voronoi diagram with the period Q in the x-direction and the period P in the y-direction in FIG. 3. The average number A of intersections in the corridor portion was 49, and the average number X of intersections in the unit area at the center of the diamond portion was 51.

### <Optically Transparent Conductive Material 7>: Present Invention

An optically transparent conductive material 7 including a metal silver image as the lower electrode layer was produced as in the optically transparent conductive material 2, except a different transparent manuscript was used which was produced by changing the pattern of the transparent manuscript from the one shown in FIG. 2 to the one shown in FIG. 3, reversing the x-direction and the y-direction in the Voronoi diagram shown in FIG. 7 (i.e., an image pattern in a region defined by “the total width of one diamond portion and one corridor portion in the x-direction”×“the entire width in the y-direction” in FIG. 7), and repeatedly attaching the Voronoi diagram with the period Q in the x-direction and the period P in the y-direction in FIG. 3. The average number A of intersections in the corridor portion was 54, and the average number X of intersections in the unit area at the center of the diamond portion was 51.

### <Optically Transparent Conductive Material 8>: Present Invention

An optically transparent conductive material 8 including a metal silver image as the lower electrode layer was obtained as in the optically transparent conductive material 7, except that the transparent manuscript was changed to one including the Voronoi diagram used in the optically transparent conductive material 3. The average number A of intersections in the corridor portion was 60, and the average number X of intersections in the unit area at the center of the diamond portion was 51.

### <Optically Transparent Conductive Material 9>: Comparative Example

An optically transparent conductive material 9 including a metal silver image as the lower electrode layer was obtained as in the optically transparent conductive material 7, except that the transparent manuscript was changed to one including the Voronoi diagram used in the optically transparent conductive material 4. The average number A of intersections in the corridor portion was 62, and the average number X of intersections in the unit area at the center of the diamond portion was 51.

### <Optically Transparent Conductive Material 10>: Comparative Example

An optically transparent conductive material 10 including a metal silver image as the lower electrode layer was obtained as in the optically transparent conductive material 7, except that the transparent manuscript was changed to one including the Voronoi diagram used in the optically transparent conductive material 5. The average number A of intersections in the corridor portion was 64, and the average number X of intersections in the unit area at the center of the diamond portion was 51.

### Evaluation of ESD Resistance

The optically transparent conductive materials 1 to 10 were tested to evaluate the ESD resistance according to the following procedure. First, the electrical resistance across the ends of each of 10 sensor parts of each optically transparent conductive material was measured using a tester. Then, the optically transparent conductive material was superimposed on a copper plate in such a manner that there was no contact between the surface with the metal silver image and the copper plate. Further, a 100-μm thick polyethylene terephthalate film was placed on the surface with the metal silver image, and seasoning was performed at 23° C. and 50% for one day. Subsequently, an electrostatic breakdown tester (DITO ESD Simulator available from EM TEST, hereinafter referred to as “DITO”) was used to perform an electrostatic breakdown test. For the electrostatic breakdown test, a DM1 was used as a discharge tips. Then, a ground wire of DITO was attached to the copper plate, and the tip of DITO was brought into contact with the 100-μm thick PET film, at a central portion in the direction in which each sensor part extended. Electrostatic discharge was performed one time for each sensor at a voltage of 8 kV. After the discharge, the PET film was removed, and the electrical resistance across the ends of each of the 10 sensor parts was measured to evaluate the ESD resistance by comparing the electrical resistance before and after the electrostatic breakdown test. Specifically, an optically transparent conductive material in which all the 10 sensor parts showed an increase in electrical resistance by less than 5% was rated as good; an optically transparent conductive material in which one sensor part showed an increase in electrical resistance by 5% or more was rated as fair; and an optically transparent conductive material in which two or more sensor parts showed an increase in electrical resistance by 5% or more was rated as poor. Table 1 shows the results, including the average numbers A and X of intersections and their ratios (A/X). All the optically transparent conductive materials of the present invention were rated as good in the ESD resistance evaluation.

TABLE 1

| | Average number of | | | | |
|---|---|---|---|---|---|
| Optically | intersections per unit area | | | Evaluation | |
| transparent | Diamond | Corridor | | of | |
| conductive | portion | portion | | ESD | |
| material | X [number] | A [number] | A/X | resistance | Reference |
| 1 | 51 | 49 | 0.96 | Poor | Comparative |
| | | | | | Example |
| 2 | 51 | 54 | 1.06 | Good | Prensent |
| | | | | | Invention |
| 3 | 51 | 60 | 1.18 | Good | Prensent |
| | | | | | Invention |
| 4 | 51 | 62 | 1.22 | Good | Comparative |
| | | | | | Example |
| 5 | 51 | 64 | 1.25 | Good | Comparative |
| | | | | | Example |
| 6 | 51 | 49 | 0.96 | Fair | Comparative |
| | | | | | Example |
| 7 | 51 | 54 | 1.06 | Good | Prensent |
| | | | | | Invention |
| 8 | 51 | 60 | 1.18 | Good | Prensent |
| | | | | | Invention |
| 9 | 51 | 62 | 1.22 | Good | Comparative |
| | | | | | Example |
| 10 | 51 | 64 | 1.25 | Good | Comparative |
| | | | | | Example |

### Production of Touchscreen

The optically transparent conductive materials 1 to 10 obtained and 2-mm thick chemically strengthened glass plates were bonded together using an OCA (MHN-FWD 100 available from Nichiei Kako Co., Ltd.) to produce touchscreens 1 to 17. Specifically, each touchscreen was produced by bonding a glass plate, an OCA, one of the optically transparent conductive materials 1 to 5, an OCA, and one of the optically transparent conductive materials 6 to 10, in the stated order, in such a manner that the surface with the metal silver image of each optically transparent conductive material was oriented toward the glass plate and that these layers were aligned with each other using alignment marks (+) on the four corners.

### Evaluation of Visibility

The produced touchscreens were individually placed on a screen of a 21.5 wide liquid crystal monitor (I2267FWH available from AOC) displaying a solid white image. A touchscreen in which moire or unevenness was clearly visible was rated as poor; a touchscreen in which moire or unevenness was visible at a closer look was rated as fair; and a touchscreen in which moire or unevenness was completely invisible was rated as good. Table 2 shows the results, including the combinations of the optically transparent conductive materials. All the combinations of the optically transparent conductive materials of the present invention were rated good. It was found that use of an optically transparent conductive material having A/X of more than 1.20 reduced the visibility.

TABLE 2

| | Upper electrode layer | | | Lower electrode layer | | | |
|---|---|---|---|---|---|---|---|
| | Optically | | | Optically | | | |
| | transparent | | | transparent | | | Evaluation |
| Touch- | conductive | | | conductive | | | of |
| screen | material | A/X | Reference | material | A/X | Reference | visibility |
| 1 | 1 | 0.96 | Comparative | 6 | 0.96 | Comparative | Good |
| | | | Example | | | Example | |
| 2 | 1 | 0.96 | Comparative | 8 | 1.18 | Prensent | Good |
| | | | Example | | | Invention | |
| 3 | 1 | 0.96 | Comparative | 10 | 1.25 | Comparative | Poor |
| | | | Example | | | Example | |
| 4 | 2 | 1.06 | Prensent | 7 | 1.06 | Prensent | Good |
| | | | Invention | | | Invention | |
| 5 | 2 | 1.06 | Prensent | 8 | 1.18 | Prensent | Good |
| | | | Invention | | | Invention | |
| 6 | 2 | 1.06 | Prensent | 9 | 1.22 | Comparative | Fair |
| | | | Invention | | | Example | |
| 7 | 3 | 1.18 | Prensent | 6 | 0.96 | Comparative | Good |
| | | | Invention | | | Example | |
| 8 | 3 | 1.18 | Prensent | 7 | 1.06 | Prensent | Good |
| | | | Invention | | | Invention | |
| 9 | 3 | 1.18 | Prensent | 8 | 1.18 | Prensent | Good |
| | | | Invention | | | Invention | |
| 10 | 3 | 1.18 | Prensent | 9 | 1.22 | Comparative | Fair |
| | | | Invention | | | Example | |
| 11 | 3 | 1.18 | Prensent | 10 | 1.25 | Comparative | Poor |
| | | | Invention | | | Example | |
| 12 | 4 | 1.22 | Comparative | 7 | 1.06 | Prensent | Fair |
| | | | Example | | | Invention | |
| 13 | 4 | 1.22 | Comparative | 8 | 1.18 | Prensent | Fair |
| | | | Example | | | Invention | |
| 14 | 4 | 1.22 | Comparative | 9 | 1.22 | Comparative | Fair |
| | | | Example | | | Example | |
| 15 | 5 | 1.25 | Comparative | 6 | 0.96 | Comparative | Poor |
| | | | Example | | | Example | |
| 16 | 5 | 1.25 | Comparative | 8 | 1.18 | Prensent | Poor |
| | | | Example | | | Invention | |
| 17 | 5 | 1.25 | Comparative | 10 | 1.25 | Comparative | Poor |
| | | | Example | | | Example | |

The results in Table 1 and Table 2 show that the present invention can provide optically transparent conductive materials that provide excellent visibility without causing moire even when superimposed on a display, in which sensor parts have excellent ESD resistance.

### REFERENCE SIGNS LIST

1: upper electrode layer (optically transparent conductive layer)

2: lower electrode layer (optically transparent conductive layer)

3, 4: optically transparent support

5, 6: optically transparent conductive material

21, 31: sensor part

22, 32: a dummy part

23, 33: peripheral wiring part

24, 34: terminal area

41: corridor portion

51, 61, 62, 71, 72: frame

a, b: virtual outline

1. An optically transparent conductive material, comprising:
an optically transparent support; and
an optically transparent conductive layer on the optically transparent support, the optically transparent conductive layer being electrically connected to a terminal area and including sensor parts extending in one direction,
wherein the sensor parts are each made of an irregular net-like pattern of thin metal wires,
each sensor part has varying widths and includes corridor portions where the width of the sensor part is relatively narrow and other portions where the width of the sensor part is relatively wide, and
the following relation is satisfied:
1.05X≤A≤1.20X,
where A is an average number of intersections in the pattern of thin metal wires per unit area in the corridor portions, and X is an average number of intersections in the pattern of thin metal wires per unit area in other portions.

2. The optically transparent conductive material according to claim 1, wherein the sensor parts extending in one direction each have a shape in which the corridor portions appear periodically.

3. The optically transparent conductive material according to claim 2, wherein the corridor portions each have a width of 1 to 2 mm and a length of 1.5 to 3 mm.

4. The optically transparent conductive material according to claim 1, wherein when the unit area is the area of one corridor portion, the A is 10 or more.

5. The optically transparent conductive material according to claim 1, wherein the irregular net-like shape is a Voronoi diagram and/or a shape obtained by deforming a Voronoi diagram.

6. The optically transparent conductive material according to claim 2, wherein when the unit area is the area of one corridor portion, the A is 10 or more.

7. The optically transparent conductive material according claim 3, wherein when the unit area is the area of one corridor portion, the A is 10 or more.

8. The optically transparent conductive material according to claim 2, wherein the irregular net-like shape is a Voronoi diagram and/or a shape obtained by deforming a Voronoi diagram.

9. The optically transparent conductive material according to claim 3, wherein the irregular net-like shape is a Voronoi diagram and/or a shape obtained by deforming a Voronoi diagram.

10. The optically transparent conductive material according to claim 4, wherein the irregular net-like shape is a Voronoi diagram and/or a shape obtained by deforming a Voronoi diagram.
